(19) United States
(12) Patent Application Publication
(10) Pub. No.: US 2025/0383165 A1
(43) Pub. Date: Dec. 18, 2025

(54) WATER-COOLING HEAT DISSIPATION DEVICE WITH SCREW CONNECTION STRUCTURES

(71) Applicant: KUAN DING INDUSTRIAL CO., LTD., New Taipei City (TW)

(72) Inventors: Kuan-Da PAN, New Taipei City (TW); Ming-Cheng PENG, New Taipei City (TW)

(21) Appl. No.: 19/062,098

(22) Filed: Feb. 25, 2025

(30) Foreign Application Priority Data
Jun. 13, 2024 (TW) 113206197

(51) Int. Cl. F28F 3/04

(52) U.S. Cl. CPC F28F 3/04; F28F 2230/00; F28F 2250/08; F28F 2275/10

(57) ABSTRACT

A water-cooling heat dissipation device (1) includes a lower shell (10), a water-cooling plate set (20), an upper shell (30), and a water pump set (40) located in the upper shell (30). The lower shell (10) includes a heat exchange space (11), a water collection space (12), and a connecting port (13). The lower shell (10) includes a connecting opening (14), and the connecting opening (14) is provided with first threads (15). The upper shell (30) includes an external installation space (31) and an internal installation space (32). The upper shell (30) is provided with second threads (15). The upper shell (30) is combined with the lower shell (10) through the second threads (15) engaging with the first threads (15).

### BACKGROUND OF THE DISCLOSURE

### Technical Field

The technical field relates to a water-cooling device, and particularly to a water-cooling heat dissipation device with screw connection structures.

### Description of Related Art

A water cooling system mainly includes a water tank, a water cooling head attached to a heating element, a pump connected to the water tank, and connecting pipes. The water cooling system uses a water cooling head attached to the surface of a heating element for heat exchange and increases the circulation efficiency through a water pump to achieve the purpose of cooling the heating element.

Furthermore, the aforementioned water cooling system is assembled by placing a water pump in a housing, and then multiple screws are used to combine the housing and the water tank. However, this combination method is complicated and time-consuming, leading to inconvenience in assembly and thus needs to be improved.

In view of the above drawbacks, the inventor proposes this disclosure based on his expert knowledge and elaborate researches in order to solve the problems of related art.

### SUMMARY OF THE DISCLOSURE

This disclosure provides a water-cooling heat dissipation device for quick assembly and prevention of water leakage.

This disclosure is a water-cooling heat dissipation device including a lower shell, a water-cooling plate set, an upper shell, and a water pump set. The lower shell includes a heat exchange space, a water collection space, and a connecting port communicating with both the heat exchange space and the water collection space. The lower shell includes a connecting opening located on one side of the water collection space, and the connecting opening is provided with a plurality of first threads. The water-cooling plate set is combined with the lower shell and covers one side of the heat exchange space. The upper shell includes an external installation space and an internal installation space arranged spacedly. The upper shell is provided with a plurality of second threads and is combined with the lower shell through the second threads engaging with the first threads. The water pump set includes a stator structure and a rotor structure. The stator structure is located in the external installation space, and the rotor structure is positioned in the internal installation space and extends into the water collection space.

In one embodiment of this disclosure, the water-cooling heat dissipation device further includes a sealing ring sandwiched between the lower shell and the upper shell, and the sealing ring is located on one side of the first threads and the second threads.

In one embodiment of this disclosure, the first threads are internal threads and the second threads are external threads.

In one embodiment of this disclosure, the water-cooling plate set includes a conduction plate and a plurality of fins arranged on the conduction plate, and the fins are located in the heat exchange space.

In one embodiment of this disclosure, the water-cooling heat dissipation device further includes a water dividing seat arranged between the conduction plate and the lower shell.

In one embodiment of this disclosure, the water-cooling heat dissipation device further includes a fastener, wherein the lower shell includes a plurality of slots, and the fasteners are inserted in the slots.

In one embodiment of this disclosure, the rotor structure includes a shaft seat, a magnetic component arranged in the shaft seat, a fixed shaft passing through the shaft seat, and a fan wheel coupled to the shaft seat, and the fan wheel is located in the water collection space.

In one embodiment of this disclosure, the lower shell includes a support column disposed in the connecting port. One end of the fixed shaft is fixed to the upper shell, and another end of the fixed shaft is secured within the support column.

In one embodiment of this disclosure, the lower shell includes an inlet pipe and an outlet pipe communicating with the water collection space.

In one embodiment of this disclosure, the water cooling heat dissipation device further includes a control panel, and the control panel is disposed on the upper shell seat and located on a top side of the water pump set.

In comparison with the related art, the lower shell of the water-cooling heat dissipation device in this disclosure is provided with multiple first threads located on the connecting opening, and the upper shell is provided with multiple second threads correspondingly. Accordingly, the upper shell and the lower shell of the water-cooling heat dissipation device are combined through the second threads engaging with the first threads. Furthermore, a sealing ring is sandwiched between the lower shell and the upper shell to ensure the sealing capability therebetween. Therefore, the water-cooling heat dissipation device may be assembled quickly, prevent leakage and increase the convenience and practicality of assembling the water-cooling heat dissipation device.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 depicts a perspective schematic view of the water-cooling heat dissipation device according to this disclosure.

FIG. 2 depicts an exploded schematic view of the water-cooling heat dissipation device according to this disclosure.

FIG. 3 depicts a cross-sectional exploded view of the water-cooling heat dissipation device according to this disclosure.

FIG. 4 depicts a combined cross-sectional view of the water-cooling heat dissipation device according to this disclosure.

FIG. 5 depicts another combined cross-sectional view of the water-cooling heat dissipation device according to this disclosure.

FIG. 6 depicts a cross-sectional exploded view from another side of the water-cooling heat dissipation device according to this disclosure.

FIG. 7 depicts an application schematic view of the water-cooling heat dissipation device according to this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

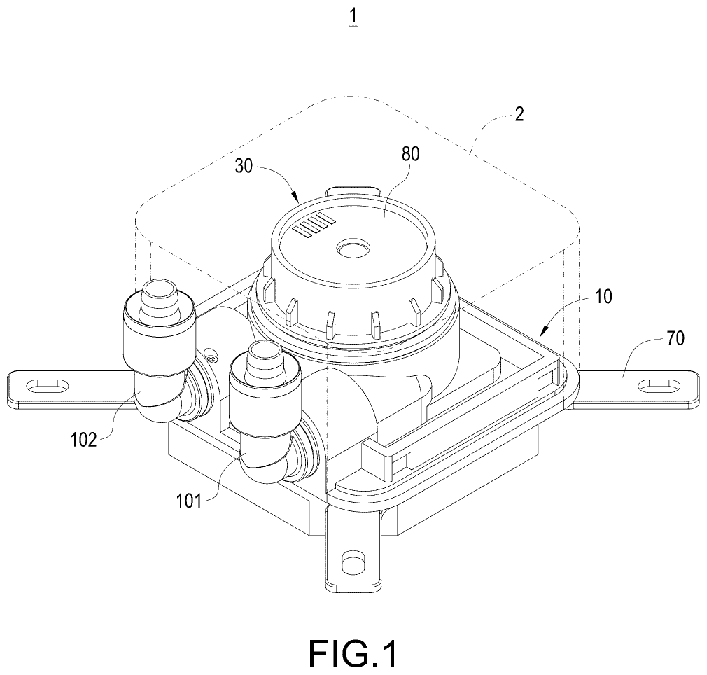

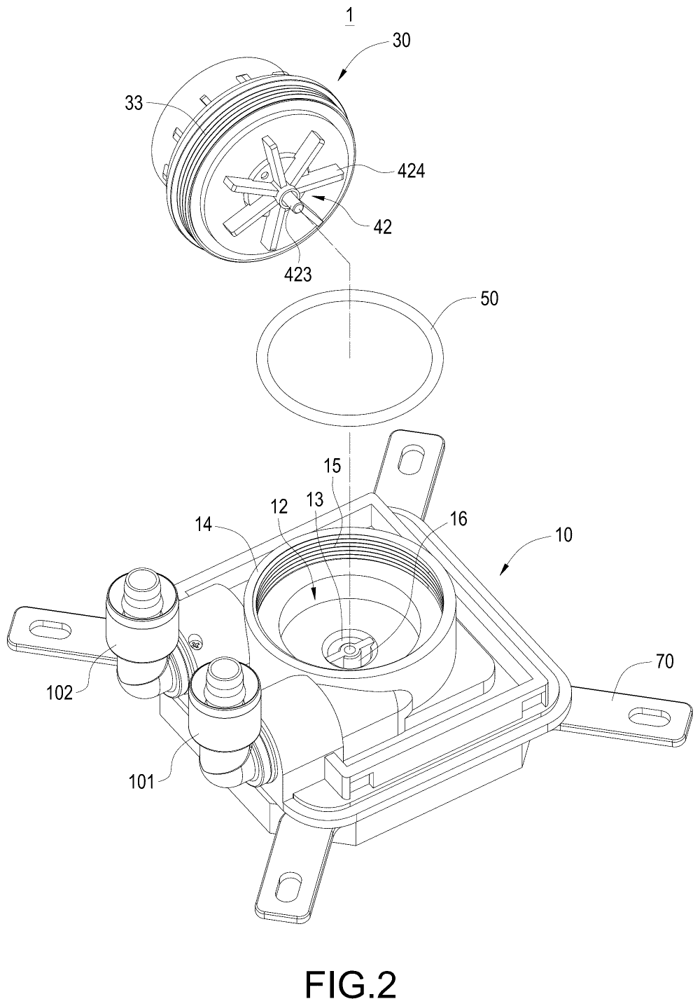

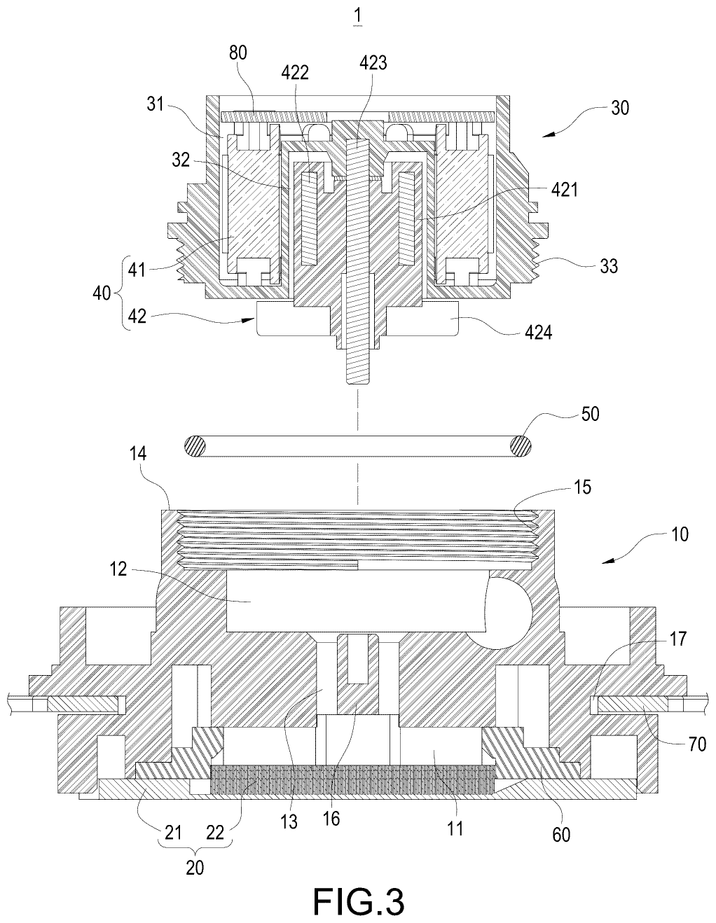

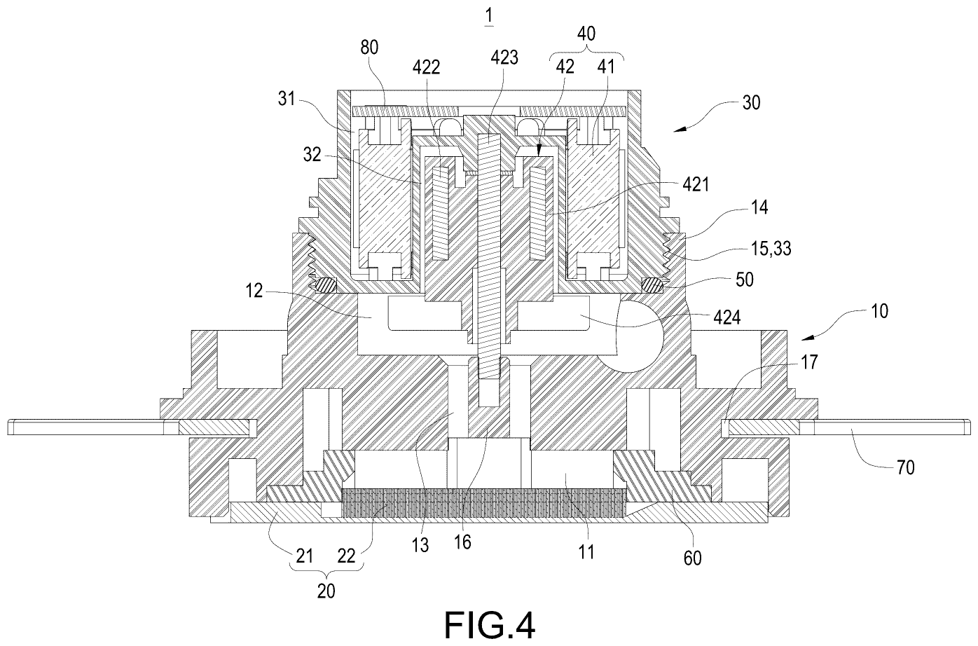

Please refer to FIG. 1 to FIG. 4, which depict a perspective schematic view of the water-cooling heat dissipation device according to this disclosure, an exploded schematic view of the water-cooling heat dissipation device according to this disclosure, a cross-sectional exploded view of the water-cooling heat dissipation device according to this disclosure, and a combined cross-sectional view of the water-cooling heat dissipation device according to this disclosure. The water-cooling heat dissipation device 1 of this disclosure includes a lower shell 10, a water-cooling plate set 20, an upper shell 30, and a water pump set 40. The water-cooling plate set 20 is coupled to the bottom side of the lower shell 10. The water pump set 40 is installed in the upper shell 30, and the upper shell 30 is coupled to the lower shell 10 through a screw connection structure. In some embodiments, the water-cooling heat dissipation device 1 further includes a housing 2. The housing 2 covers the upper shell 30 and is combined with the lower shell 10. A more detailed description of the water-cooling heat dissipation device 1 is as follows.

The lower shell 10 includes a heat exchange space 11, a water collection space 12, and a connecting port 13 that communicates with both the heat exchange space 11 and the water collection space 12. The connecting port 13 is configured to allow the water in the collection space 12 to flow into the heat exchange space 11 through the connecting port 13. Additionally, the lower shell 10 includes a connecting opening 14 located on one side of the water collection space 12, and the connecting opening 14 is provided with a plurality of first threads 15. In this embodiment, the lower shell 10 further includes an inlet pipe 101 and an outlet pipe 102 that communicate with the water collection space 12.

The water-cooling plate set 20 is combined with the lower shell 10 and covers one side of the heat exchange space 11. In this embodiment, the water-cooling plate set 20 includes a conduction plate 21 and a plurality of fins 22 arranged on the conduction plate 21, and the fins 22 are located in the heat exchange space 11.

The upper shell 30 includes an external installation space 31 and an internal installation space 32 arranged spacedly. The upper shell 30 is provided with a plurality of second threads 33. The upper shell 30 is combined with the lower shell 10 through the second threads 33 engaging with the first threads 15.

Moreover, the water pump set 40 includes a stator structure 41 and a rotor structure 42. The stator structure 41 is located in the external installation space 31. The rotor structure 42 is positioned in the internal installation space 32 and extends into the water collection space 12.

Specifically, the rotor structure 42 includes a shaft seat 421, a magnetic component 422 arranged in the shaft seat 421, a fixed shaft 423 passing through the shaft seat 421, and a fan wheel 424 coupled to the shaft seat 421. After the upper shell 30 is screwed to the lower shell 10, the fan wheel 424 is located in the water collection space 12, and the fan wheel 424 is structured by a plurality of blades. Additionally, the lower shell 10 includes a support column 16 disposed in the connecting port 13. One end of the fixed shaft 423 is fixed to the upper shell 30, and the other end of the fixed shaft 423 is secured in the support column 16.

In this embodiment, the water-cooling heat dissipation device 1 further includes a sealing ring 50. The sealing ring 50 is sandwiched between the lower shell 10 and the upper shell 3 and is located on one side of the first threads 15 and the second threads 33. The sealing ring 50 is used to maintain the seal between the lower shell 10 and the upper shell 30.

Furthermore, the water-cooling heat dissipation device 1 further includes a water dividing seat 60 arranged between the conduction plate 21 and the lower shell 10. The water dividing seat 60 is used to separate the inflow and outflow of water and to prevent turbulence that may affect the movement of the water flow.

In this embodiment, the first threads 15 are internal threads, and the second threads 33 are external threads. In some embodiments, the first threads 15 may be external threads, and the second threads 33 may be internal threads.

It is worth noticing that the water-cooling heat dissipation device 1 further includes a fastener 70. Additionally, the lower shell 10 includes a plurality of slots 17. Furthermore, the fasteners 70 are inserted in the slots 17. The water-cooling heat dissipation device 1 is positioned at a fixed position through the arrangement of the fastener 70.

It should be noted that the water-cooling heat dissipation device 1 further includes a control panel 80. The control panel 80 is arranged on the upper shell 30 and is located on the top side of the water pump set 40. Accordingly, an external device may control the operation of the water pump set 40 by the electrical connection with the control board 80.

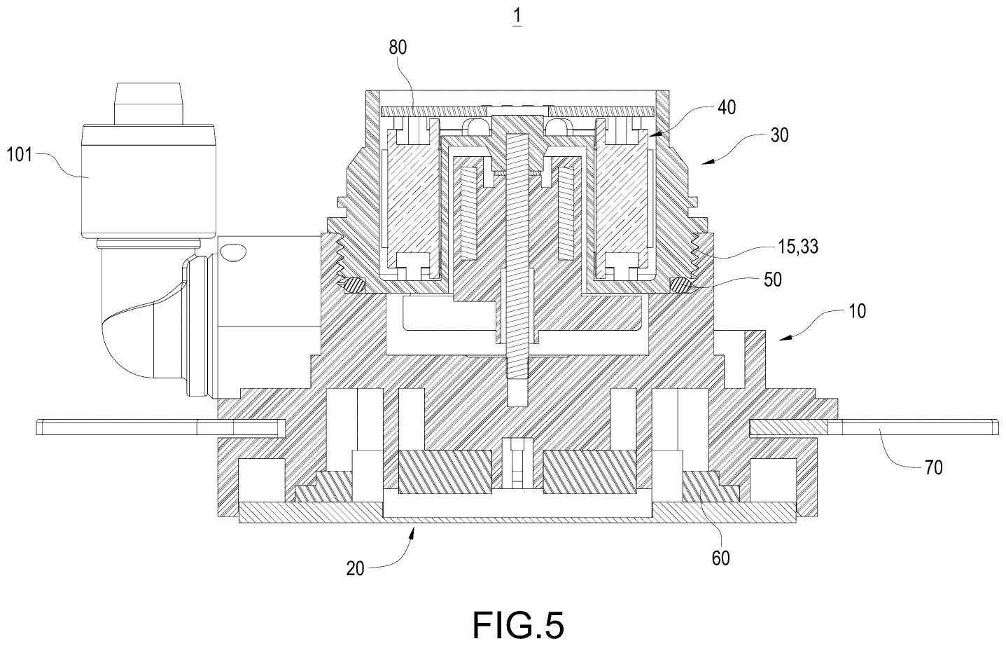

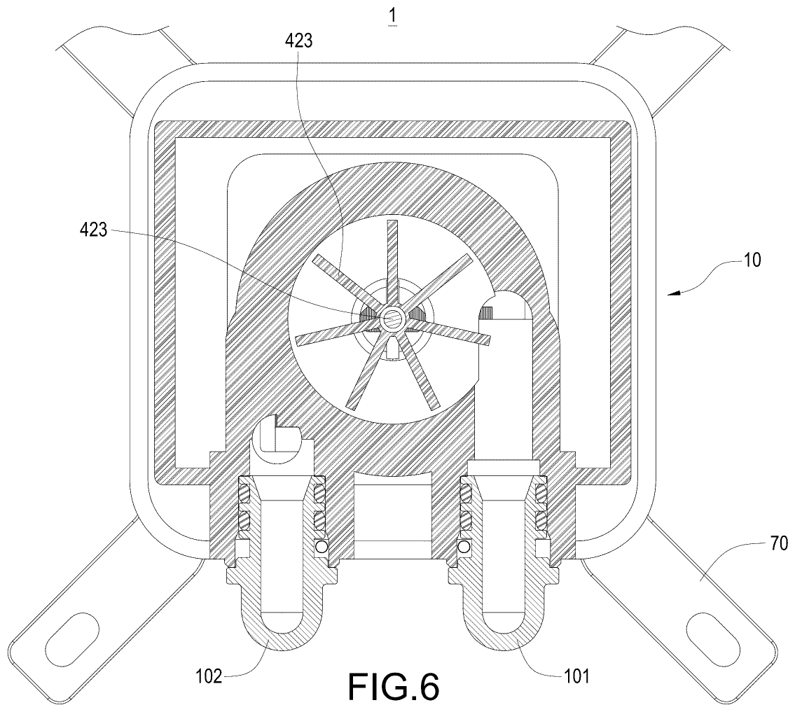

Please refer to FIG. 5 and FIG. 6, which are another combined cross-sectional view of the water-cooling heat dissipation device according to this disclosure and a cross-sectional exploded view from another side of the water-cooling heat dissipation device according to this disclosure. The upper shell 30 of the water-cooling heat dissipation device 1 is combined with the lower shell 10 by the second threads 33 engaging with the first threads 15. Furthermore, the sealing ring 50 is sandwiched between the lower shell 10 and the upper shell 30 to ensure the sealing capability therebetween. Therefore, the water-cooling heat dissipation device 1 is assembled quickly and may avoid the occurrence of water leakage to increase the convenience and practicality of assembling the water-cooling heat dissipation device 1 of this disclosure.

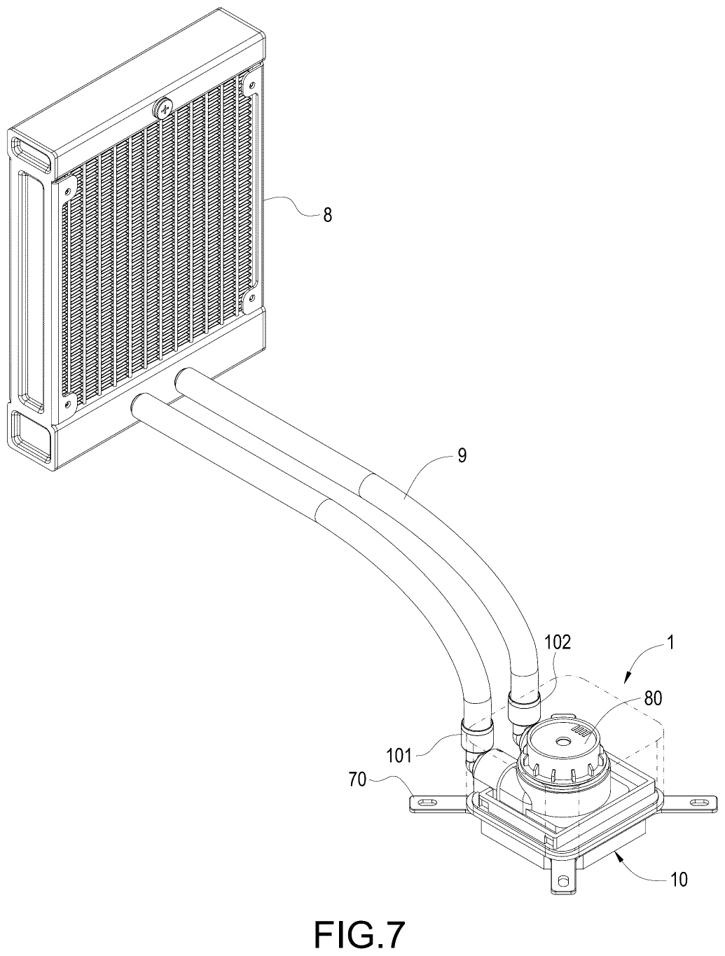

Please refer to FIG. 7, which depicts an application schematic view of the water-cooling heat dissipation device according to this disclosure. The application of the water-cooling heat dissipation device 1 of this disclosure may be combined with a water-cooling radiator 8 and a plurality of connecting pipes 9. The connecting pipes 9 are arranged between the water-cooling radiator 8 and the water-cooling heat dissipation device 1. Accordingly, the water (coolant) from the water-cooling heat dissipation device 1 is transported to the water-cooling radiator 8 through the connecting pipes 9, and heat is exchanged with the water-cooling radiator 8, and finally returns to the water-cooling heat sink 1 for circulation.

While this disclosure has been described by means of specific embodiments, numerous modifications and variations may be made thereto by those skilled in the art without departing from the scope and spirit of this disclosure set forth in the claims.

What is claimed is:

1. A water-cooling heat dissipation device, comprising:
a lower shell (10), comprising a heat exchange space (11), a water collection space (12), a connecting port (13) communicating with the heat exchange space (11) and the water collection space (12), a connecting opening (14) located on one side of the water collection space (12), and a plurality of first threads (15) located on the connecting opening (14);
a water-cooling plate set (20), combined with the lower shell (10) and covering one side of the heat exchange space (11);
an upper shell (30), comprising a plurality of second threads (15), and an external installation space (31) and an internal installation space (32) arranged spacedly, wherein the upper shell (30) is combined with the lower shell (10) through the second threads (15) engaging with the first threads (15); and
a water pump set (40), comprising a stator structure (41) and a rotor structure (42), wherein the stator structure (41) is located in the external installation space (31), and the rotor structure (42) is positioned in the internal installation space (32) and extends into the water collection space (12).

2. The water-cooling heat dissipation device according to claim 1, further comprising a sealing ring (50) sandwiched between the lower shell (10) and the upper shell (30), wherein the sealing ring (50) is located on one side of the first threads (15) and the second threads (33).

3. The water-cooling heat dissipation device according to claim 1, wherein the first threads (15) are internal threads and the second threads (33) are external threads.

4. The water-cooling heat dissipation device according to claim 1, wherein the water-cooling plate set (20) comprises a conduction plate (21) and a plurality of fins (22) arranged on the conduction plate (21), and the fins (22) are located in the heat exchange space (11).

5. The water-cooling heat dissipation device according to claim 4, further comprising a water dividing seat (60) arranged between the conduction plate (21) and the lower shell (10).

6. The water-cooling heat dissipation device according to claim 1, further comprising a fastener (70), wherein the lower shell (10) comprises a slot (17), and the fastener (70) is inserted in the slot (17).

7. The water-cooling heat dissipation device according to claim 1, wherein the rotor structure (42) comprises a shaft seat (421), a magnetic component (422) arranged in the shaft seat (421), a fixed shaft (423) passing through the shaft seat (421), and a fan wheel (424) coupled to the shaft seat (421), and the fan wheel (424) is located in the water collection space (12).

8. The water-cooling heat dissipation device according to claim 7, wherein the lower shell (10) comprises a support column (16) disposed in the connecting port (13); one end of the fixed shaft (423) is fixed to the upper shell (30), and another end of the fixed shaft (423) is secured in the support column (16).

9. The water-cooling heat dissipation device according to claim 1, wherein the lower shell (10) comprises an inlet pipe (101) and an outlet pipe (102) communicating with the water collection space (12).

10. The water-cooling heat dissipation device according to claim 1, further comprising a control panel (80), wherein the control panel (80) is disposed on the upper shell seat (30) and located on a top side of the water pump set (40).
